(19) United States
(12) Patent Application Publication
(10) Pub. No.: US 2008/0167754 A1
(43) Pub. Date: Jul. 10, 2008

(54) OZONE AND OTHER MOLECULES SENSORS FOR ELECTRIC FAULT DETECTION

(76) Inventors: Sarah C. McAllister, Ossining, NY (US); Tomasz J. Nowicki, Fort Montgomery, NY (US); Grzegorz M. Swirszoz, Ossining, NY (US); Jeffrey D. Taft, Canonsburg, PA (US)

Correspondence Address: Whitham Curtis & Christofferson, P.C., Suite 340, 11491 Sunset Hills Road, Reston, VA, 20190, US

(21) Appl. No.: 11/620,083

(22) Filed: Jan. 5, 2007

(51) Int. Cl. H02H 7/26; G01R 31/08; H02J 13/00

(52) U.S. Cl. 700/293; 702/59; 307/103

(57) ABSTRACT

High impedance fault detection uses, in addition to sensors that measure purely electrical (i.e., current and voltage), molecule sensors are provided in an electrical grid. These molecule sensors are sensitive to the surrounding environment and may detect one or more of a variety of molecules, such as ozone (O₃), combustion gases (carbon monoxide, carbon dioxide and oxygen levels), and odor molecules (ammonia, sulfur dioxide, burned hair/feather, burned proteins, and the like), depending on the type of environmental phenomena that may be expected in a particular location of the sensor(s). These sensors, in combination with conventional electrical sensors, provide a more complete set of data for evaluation and localization of a potential high impedance electrical fault. The use of such sensors is especially useful in confined areas like underground parking lots, substations, and the like.

### BACKGROUND OF THE INVENTION

1. Field of the Invention

The present application generally relates to the detection of high-impedance faults in electrical power grids and, more particularly, to a new category of senor for deployment throughout an electrical grid and which is capable of detecting environmental conditions which are associated with a high impedance fault.

2. Background Description

High impedance faults are costly, dangerous to the equipment and a threat to human life. There is a huge diversity of phenomena classified as high impedance faults. These include, but are not limited to, a downed line, a tree branch touching a line, a broken insulator, and improper installation. As a result, there is no accepted scientific knowledge about the nature of high impedance fault detection.

Electrical power grids are extremely complicated, making the detection and localization of a high impedance fault difficult and problematic. Current methods of detection include circuit breakers tripping, readout from meters at the substation by human operators, and a telephone call from someone who noticed a fault. Interestingly, the last of these methods, e.g., a telephone call, is the most common method by which faults are detected and located. There have been attempts to use local sensors that automatically make a decision and either raise an alarm or disconnect a part of the grid. These attempts have proven to be unsatisfactory due to the lack the ability to flexibly adapt to the specifics of a particular environment. The sensors which have been used in the past have monitored electrical attributes, i.e., voltage and current, from the wires. However, such data “from the wires” may propagate a considerable distance, making localization of the actual fault difficult.

### SUMMARY OF THE INVENTION

The inventors have correlated specific molecules in the environment, especially ozone, to high impedance electrical faults. Such faults are often accompanied by sparking and ionization. The corona discharge or ultraviolet light that occurs causes, for example, oxygen molecules to split into individual atoms which, upon recombining with another oxygen molecule, produce an ozone molecule. Also, some common high impedance faults are due to electrocuted animals (e.g., squirrels and birds) which can be detected by molecule detectors due to decomposition of the animal flesh.

According to the present invention, in addition to sensors that measure purely electrical (i.e., current and voltage), molecule sensors are provided in an electrical grid which sensors are sensitive to the surrounding environment. These sensors may detect one or more of a variety of molecules, such as ozone (O₃), combustion gases (carbon monoxide (CO), carbon dioxide (CO₂) and oxygen (O₂) levels), and odor molecules (ammonia (NH₃), sulfur dioxide (SO₂), burned hair/feather, burned proteins, and the like), depending on the type of environmental phenomena that may be expected in a particular location of the sensor(s). The intensities of the molecules may be collected by Ion Selective Electrodes (ISE), e.g., diodes, or other specialized sensors. These sensors, in combination with conventional electrical sensors, provide a more complete set of data for evaluation and localization of a potential high impedance electrical fault. The use of such sensors is especially useful in confined areas like underground parking lots, substations, and the like.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 is a high level block diagram illustrating the general concept of a two-stage high impedance fault detection system employing both electrical and environmental molecule detectors according to the invention; and

FIG. 2 is a flow chart illustrating the process of sensing of specific environmental molecules for the detection of high impedance faults.

### DETAILED DESCRIPTION OF A PREFERRED EMBODIMENT OF THE INVENTION

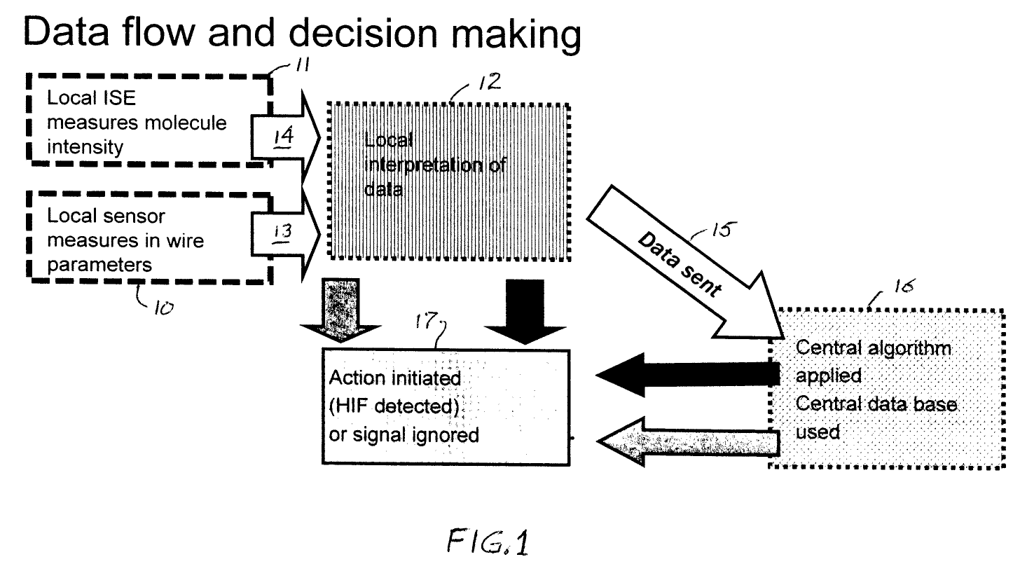

Referring now to FIG. 1 of the drawings, there is illustrated in block diagram from the basic concept of a two-stage high impedance fault detection system which incorporates both electrical and environmental sensors according to the invention. The first stage comprises a collection of voltage/current sensors deployed over the power grid. These voltage/current sensors are supplemented by one or more environmental sensors, such as ozone (O₃), combustion gases (carbon monoxide (CO), carbon dioxide (CO₂), and oxygen (O₂) levels), and odor molecules (ammonia (NH₃), sulfur dioxide (SO₂), burned hair/feathers, burned proteins, and the like) sensors, depending on environmental conditions that are anticipated. The intensities of the molecules are collected locally by Ion Selective Electrodes (ISE), i.e., diodes, or other specialized sensors. A single one of the voltage/current sensors 10 and a single one of the environmental sensors 11 are illustrated for the purposes of this description, but it will be understood that many such voltage/current sensors 10 are deployed over the entire grid and that one or more environmental sensors 11 may be deployed at any one location. Next to each voltage/current sensor 10 and environmental sensor 11 there is located a remote processing unit which performs a pre-analysis of the signal from its associated sensors. Again, a single one of the remote processor units 12 is illustrated for the purposes of this description. Each of the remote processor units is capable of sampling, pre-processing and pre-qualifying signals 13 and 14 from its respective associated sensors. The signal readouts from the sensors are constantly monitored and analyzed online by their remote processor unit. Fast algorithms of data analysis are implemented on each remote processor unit. Whenever a readout is identified as not typical, the transmission to the central processor unit is initiated. In FIG. 1, this is illustrated by the data signal 15 transmitted to central processor unit 16, which constitutes the second stage of the two-stage high impedance fault detection system illustrated in FIG. 1. This transmission may be implemented by broadband power line (BPL) technology or by wireless transmission, or a combination of both as will be discussed in more detail hereinafter. The central processor unit 16 analyzes the data further, taking advantage of more resources than are available to the individual remote processing units.

Only those individual predictions from remote sensor units determined to be not typical are transmitted to the central processor unit. Several remote processor units may be aggregated for transmission of data to the central processor unit for the second stage of fault detection and analysis. This transmission can be by means of broadband power line technology (BPL) or wireless transmission or the combination of the two. For example, several remote processor units can be grouped into a wireless local area network (LAN) which communicates with a transmitter centrally located to that particular wireless local area network. If the technology used is limited to BPL, each remote processor unit would have a connection to the central processor unit to be able to be able to transmit the amount of data equivalent to two to five seconds or more of sampled readout of its associated sensor. Other technologies can be used to transmit the data.

Action can be initiated either locally or centrally, as generally indicated by block 17. For example, the local interpretation of the data from the sensors 10 and 11 by the processor unit 12 may result in one of three actions. First, if the interpreted data indicates a high impedance fault, an automated circuit breaker function can be initiated. If, however, the interpreted data, while identified as not typical, is inconclusive as to the occurrence of a high impedance fault, the data is sent to central processor 16 for further analysis. Finally, if the interpreted data is determined to be typical, the data is ignored and no further action is taken. At the central processor 16, the data sent by the remote processor is further analyzed, and this analysis may result in one of three actions. First, if the interpreted data indicates a high impedance fault an automated circuit breaker function can be initiated. At the same time, an alarm and a display is generated to alert a human operator of the action taken. If, however, the interpreted data is not conclusive as to indicating a high impedance fault, the central processing unit 16 may generate an alarm, either audibly, visually or both, and provide a display to a human operator with a prompt to take some further action. Finally, if upon further analysis it is determined that no high impedance fault has occurred, the data is ignored.

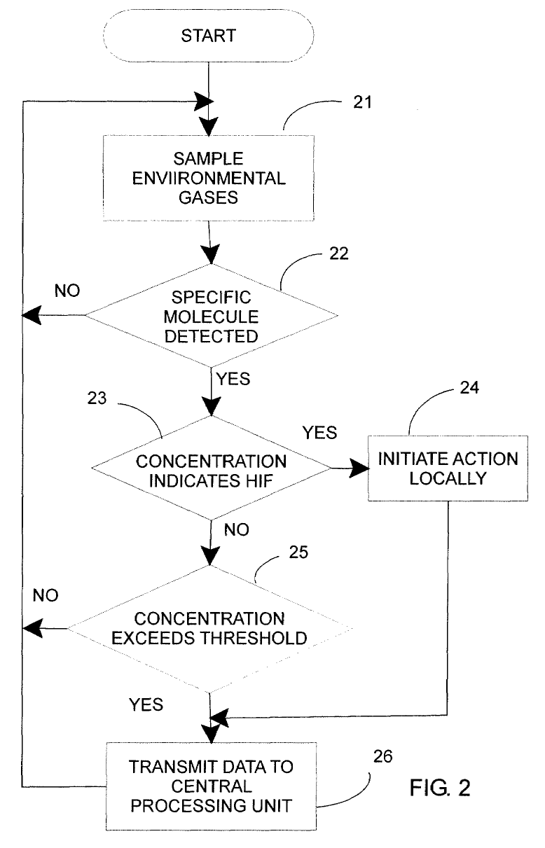

The process implemented of sensing of specific environmental molecules for the detection of high impedance faults is illustrated in FIG. 2. The process begins by sampling environmental gases in function block 21. A determination is made in decision block 22 as to whether a specific molecule is detected. The molecule may be ozone, combustion gases, or odor molecules, depending on the environmental conditions anticipated. If the specific molecule is not detected, the process returns to function block 21 to continue to sample environmental gases. If, however, the specific molecule is detected, a further determination is made in decision block 23 to determine if the concentration of the specific molecule detected indicates a high impedance fault. Such a determination would, in practice, be made in combination with data from the output of electrical parameter sensors. If a high impedance fault is detected, action may be initiated locally, as indicated by function block 24. If no high impedance fault is determined, a further determination is made in decision block 25 as to whether the concentration of the detected molecule exceeds some predetermined threshold. If not, the process returns to function block 21 to continue to sample environmental gases. If, however, the threshold is exceeded, the data is transmitted to the central processing unit in function block 26, and the process returns to function block 21 to continue to sample environmental gases. Should an action be initiated locally as indicated by function block 24, the process would then go to function block 26 in order that this action is transmitted to the central processing unit.

Although the invention has been described in terms of a two-stage detection system, it will be understood by those skilled in the art that the environment sensors, as well as any accompanying current/voltage sensors, may be configured to communicate directly with a central processor without the use of remote processors in a single stage detection system. Thus, while the invention has been described in terms of a single preferred embodiment, those skilled in the art will recognize that the invention can be practiced with modification within the spirit and scope of the appended claims.

Having thus described our invention, what we claim as new and desire to secure by Letters Patent is as follows:

1. A system for the detection and localization of electric faults in power grids and circuits comprising:
a plurality of remote sensor units deployed throughout a power grid, said remote sensor units including electrical sensors at each of a plurality of locations of the power grid and one or more environmental sensors at at least one location of the plurality of locations of the power grid, said environmental sensors being capable of detecting molecules indicative of an anticipated environmental condition;
means for transmitting data indicating electrical and environmental conditions from one or more remote sensor units; and
a central processor unit receiving data transmitted from said means for transmitting and analyzing said data to identify and locate a fault condition.

2. The system for detection and localization of electric faults in power grids and circuits recited in claim 1, wherein said environmental sensors are capable of detecting one of ozone, combustion gases and odor molecules.

3. The system for detection and localization of electric faults in power grids and circuits recited in claim 1, further comprising a plurality of remote processor units each associated with a corresponding one or more of said remote sensor units, each of said plurality of remote processor units sampling, pre-processing and pre-qualifying signals from its associated remote sensor units and making an initial identification of a not typical condition, said preprocessor unit transmitting data to the central processor unit.

4. A method for the detection and localization of electric faults in power grids and circuits, comprising the steps of:
sampling environmental gases in one or more locations of a power grid to detect molecules indicative of an anticipated environmental condition;
determining if at least one specific molecule indicative of an anticipated environmental condition has been detected; and
transmitting information indicating detection of at least one specific molecule indicative of an anticipated environmental condition to a central processing unit.

5. The method for the detection and localization of electric faults in power grids and circuits recited in claim 4, further comprising the steps of:
after determining if at least one specific molecule indicative of an anticipated environmental condition has been detected, determining if a concentration of the detected molecule indicates a high impedance fault; and
if so, initiating a remedial action locally before transmitting information to said central processing unit.

6. The method for the detection and localization of electric faults in power grids and circuits recited in claim 4, further comprising after the step of determining if at least one specific molecule indicative of an anticipated environmental condition has been detected, determining if a concentration of the detected molecule exceeds a predetermined threshold and, if so, performing the step of transmitting information indicating detection of at least one specific molecule indicative of an anticipated environmental condition to said central processing unit but otherwise suppressing said step of transmitting.

7. The method for detection and localization of electric faults in power grids and circuits recited in claim 4, wherein said environmental gases detected are one of ozone, combustion gases and odor molecules.

8. A system for the detection and localization of electric faults in power grids and circuits comprising:
at least one remote sensing unit for sampling environmental gases in one or more locations of a power grid to detect molecules indicative of an anticipated environmental condition and determining if at least one specific molecule indicative of an anticipated environmental condition has been detected; and
means for transmitting information indicating detection of at least one specific molecule indicative of an anticipated environmental condition to a central processing unit.

9. The system for detection and localization of electric faults in power grids and circuits recited in claim 1, wherein said environmental sensors are capable of detecting one of ozone, combustion gases and odor molecules.
